(19) United States
(12) Patent Application Publication
(10) Pub. No.: US 2011/0001509 A1
(43) Pub. Date: Jan. 6, 2011

(54) SEMICONDUCTOR INTEGRATED CIRCUIT DEVICE AND METHOD FOR TESTING THE SAME

(75) Inventor: Toru KIDOKORO, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kanagawa (JP)

(21) Appl. No.: 12/827,974

(22) Filed: Jun. 30, 2010

(30) Foreign Application Priority Data
Jul. 3, 2009 (JP) 2009-158677

(51) Int. Cl. G01R 31/26; H01L 25/00

(52) U.S. Cl. 324/762.01; 327/565

(57) ABSTRACT

A semiconductor integrated circuit device includes: terminals 11a and 11m; first to (2n+1)-th resistive elements (n is an integer of at least 1) (resistive element group 12) connected in series between the terminals 11a and 11m; a selection circuit 14 selecting, assuming that a terminal 11a connected to one end of the first resistive element is a 0th node, a terminal 11m connected to the other end of the (2n+1)-th resistive element is a (2n+1)-th node, and a connection point of the other end of an i-th resistive element (i is an integer from 1 to 2n) and one end of an (i+1)-th resistive element is an i-th node, any one of the 0th to (2n+1)-th nodes and outputting a voltage applied to the selected node; a switch group 15a capable of shorting any 2k-th node (k is an integer from 0 to n); and a switch group 15b capable of shorting any (2k+1)-th node. The 2k-th and (2k+1)-th nodes are shorted, and subsequently, a predetermined voltage is temporarily applied between the terminals 11a and 11m.

### CROSS-REFERENCE TO RELATED APPLICATION

This application is based upon and claims the benefit of the priority of Japanese patent application No. 2009-158677 filed on Jul. 3, 2009, the disclosure of which is incorporated herein in its entirety by reference thereto.

### TECHNICAL FIELD

The present invention relates to a semiconductor integrated circuit device and a method for testing the same. In particular, it relates to a circuit and a method for testing a semiconductor integrated circuit device having a digital-to-analog (D/A) conversion function formed by a resistor divider.

### BACKGROUND

While a multi-level (gradation) liquid crystal display driver IC incorporating digital-to-analog converters (DACs) is available, such driver IC includes a single DAC for each of the liquid crystal drive output terminals therein. Depending on an inputted multi-bit digital signal (multi-level data), a DAC outputs an analog voltage from a liquid crystal drive output terminal corresponding thereto. Thus, the multi-level liquid crystal display driver IC incorporating these DACs is inspected and failures are determined by measuring the analog voltages outputted from all the DACs. In the inspection of such driver IC, the analog voltages need to be measured by a high-precision analog voltmeter.

Patent Document 1 discloses a semiconductor integrated circuit device that can be inspected by a comparator, instead of a high-precision analog voltmeter, to determine failures digitally. According to this document, the inspection time can be reduced significantly, and a high-precision inspection by using an inexpensive digital inspection device can be made. This semiconductor integrated circuit device incorporates a D/A converter including: at least two input terminals supplied with a reference power supply voltage; a resistor divider that divides a voltage between the two reference power supply voltage input terminals by using resistors to generate intermediate voltages; and a switch circuit that selects and outputs, depending on an input digital signal, any one of the above reference power supply voltage and intermediate voltages. The output voltage from the D/A converter is outputted from an output terminal of the semiconductor integrated circuit device. The semiconductor integrated circuit device further includes a switch means for partially shorting part of the above resistor divider. Based on this semiconductor integrated circuit device, a potential difference between inspected output voltages can be increased, and failures can be digitally determined by using a comparator.

Patent Document 1: Japanese Patent Kokai Publication No. JP-P2000-165244A

### SUMMARY

The entire disclosure of the above patent document is incorporated herein by reference thereto. Analysis will be hereinafter made based on the present invention.

Generally, a liquid crystal display (LCD) driver includes a resistor divider that divides a voltage into a plurality of voltages, which are applied to wirings. These wirings are arranged so as to extend in parallel to each other for a long distance. In view of life of such an LCD driver, it is desirable that voltages applied to between neighboring wirings be low. However, in order to execute screening to eliminate initial failures, application of a sufficiently high voltage between neighboring wirings is demanded.

The conventional semiconductor integrated circuit device has a test facilitating means that increases a potential difference between neighboring wirings, thereby increasing a multi-level (gradation) potential difference. However, the semiconductor integrated circuit device does not have a function of applying a screening voltage between neighboring wirings. Thus, effective screening cannot be executed, and therefore, initial failures cannot be eliminated effectively. Thus there is much to be desired in the art.

According to an aspect of the present invention, there is provided a semiconductor integrated circuit device comprising: first and second terminals; first to (2n+1)-th resistive elements (n is an integer of at least 1) connected in series between the first and second terminals; a selection circuit selecting, assuming that a first terminal connected to one end of a first resistive element is a 0th node, a second terminal connected to the other end of the (2n+1)-th resistive element is a (2n+1)-th node, and a connection point of the other end of an i-th resistive element (i is an integer from 1 to 2n) and one end of an (i+1)-th resistive element is an i-th node, any one of the 0th to (2n+1)th nodes and outputting a voltage applied to the selected node; a first switch group capable of shorting any 2k-th node (k is an integer from 0 to n), that is, all the even-numbered nodes; and a second switch group capable of shorting any (2k+1)-th node, that is, all the odd-numbered nodes.

According to another aspect of the present invention, there is provided a method for testing a semiconductor integrated circuit device, comprising: first and second terminals; first to (2n+1)-th resistive elements (n is an integer of at least 1) connected in series between the first and second terminals and capable of selecting, assuming that a first terminal connected to one end of a first resistive element is a 0th node, a second terminal connected to the other end of the (2n+1)-th resistive element is a (2n+1)-th node, and a connection point of the other end of an i-th resistive element (i is an integer from 1 to 2n) and one end of an (i+1)-th resistive element is an i-th node, any one of the 0th to (2n+1)-th nodes and outputting a voltage applied to the selected node. The method further comprises: (a) shorting any 2k-th node (k is an integer from 0 to n), that is, all the even-numbered nodes and any (2k+1)-th node, that is, all the odd-numbered nodes, termed “step (a)”; (b) temporarily applying a predetermined voltage between the first and second terminals, termed “step (b)”; and (c) opening any 2k-th node, that is, all the even-numbered nodes and any (2k+1)-th node, that is, all the odd-numbered nodes, termed “step (c)”.

The meritorious effects of the present invention are summarized as follows.

According to the present invention, voltages necessary for screening can be applied across (between) neighboring wirings, and as a result, delivery quality can be improved.

### BRIEF DESCRIPTION OF THE DRAWINGS

FIG. 1 is a circuit diagram of a semiconductor integrated circuit device according to an example of the present invention.

FIG. 2 is a layout of the semiconductor integrated circuit device according to the example of the present invention.

FIG. 3 is a flow chart illustrating a first test method of the semiconductor integrated circuit device according to the example of the present invention.

FIG. 4 is a flow chart illustrating a second test method of the semiconductor integrated circuit device according to the example of the present invention.

### PREFERRED MODES

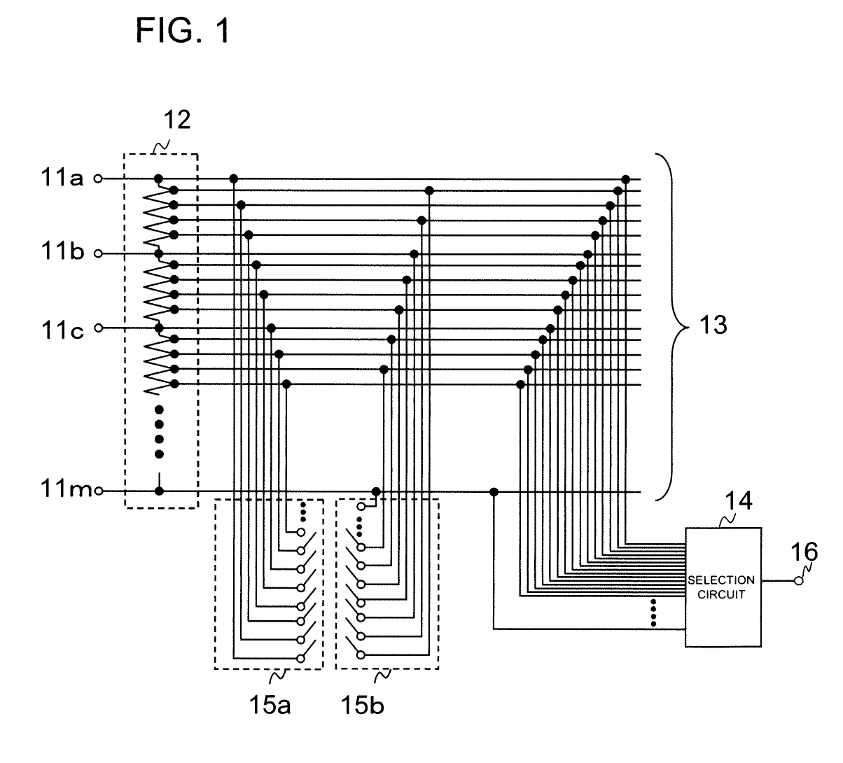

A semiconductor integrated circuit device according to an exemplary embodiment of the present invention comprises: first and second terminals (e.g., 11a and 11m in FIG. 1); first to (2n+1)-th resistive elements (n is an integer of at least 1) (e.g., 12 in FIG. 1) connected in series between the first and second terminals; a selection circuit (e.g., 14 in FIG. 1) selecting, assuming that a first terminal connected to one end of a first resistive element is a 0th node, a second terminal connected to the other end of the (2n+1)-th resistive element is a (2n+1)-th node, and a connection point of the other end of an i-th resistive element (i is an integer from 1 to 2n) and one end of an (i+1)-th resistive element is an i-th node, any one of the 0th to (2n+1)-th nodes and outputting a voltage applied to the selected node; a first switch group (e.g., 15a in FIG. 1) capable of shorting any 2k-th node (k is an integer from 0 to n), that is, all the even-numbered nodes; and a second switch group (e.g., 15b in FIG. 1) capable of shorting any (2k+1)-th node, that is, all the odd-numbered nodes.

Based on the semiconductor integrated circuit device, it is preferable that the first and second switch groups be open in a normal operation mode and be temporarily shorted in a test mode.

It is preferable that the semiconductor integrated circuit device further comprise a plurality of the selection circuits and that wirings, each extending from a corresponding one of the 0th to (2n+1)-th nodes, extend in parallel to each other to branch points of the plurality of selection circuits.

Based on the semiconductor integrated circuit device, it is preferable that the plurality of the selection circuits be arranged under a plurality of wiring arrangement regions in output cell arrangement regions.

A method for testing the above semiconductor integrated circuit device comprises: (a) shorting any 2k-th node (k is an integer from 0 to n), that is, all the even-numbered nodes and any (2k+1)-th node, that is, all the odd-numbered nodes, termed “step (a)”; (b) temporarily applying a predetermined voltage between the first and second terminals, termed “step (b)”; and (c) opening any 2k-th node, that is, all the even-numbered nodes and any (2k+1)-th node, that is, all the odd-numbered nodes, termed “step (c)”.

It is preferable that the method for testing the above semiconductor integrated circuit device further comprise (d) measuring electrical characteristics of the first to (2n+1)-th resistive elements after step (c), termed “step (d)”.

It is preferable that the method for testing the above semiconductor integrated circuit device further comprise: (a0) measuring initial electrical characteristics of the first to (2n+1)-th resistive elements before step (a), termed “step (a0)”; and (e) comparing measurement results of the electrical characteristics obtained in steps (a0) and (d) after step (d), termed “step (e)”.

According to the above test method, by shorting any 2k-th node (k is an integer 0 to n), that is, all the even-numbered nodes and any (2k+1)-th node, that is, all the odd-numbered nodes and temporarily applying a predetermined voltage between the first and second terminals, a voltage necessary for screening can be applied between neighboring wirings. Thus, effective screening can be executed and initial failures can be effectively eliminated.

The present invention will be hereinafter described in detail with reference to the accompanying drawings based on examples.

### EXAMPLE 1

FIG. 1 is a circuit diagram of a semiconductor integrated circuit device according to an example of the present invention. In FIG. 1, the semiconductor integrated circuit device includes terminals 11a to 11m, a resistive element group 12, a wiring group 13, a selection circuit 14, switch groups 15a and 15b, and an output terminal 16.

Each of the terminals 11a to 11m supplies a reference voltage supply, and the resistive element group 12 is connected between the terminals 11a and 11m. The resistive element group 12 is formed by many resistive elements connected in series, and each wiring of the wiring group 13 extends from a connection point (node) of two of the resistive elements. The selection circuit 14 selects one wiring among the wiring group 13 based on a control signal (not illustrated) and outputs a voltage applied to the selected wiring to the output terminal 16.

The point where the terminal 11a and the resistive element group 12 are connected will be hereinafter referred to as a node 0, and the point where the terminal 11m and the resistive element group 12 are connected will be hereinafter referred to as a node 2n+1. Further, from top to bottom in FIG. 1, intermediate connection points of the resistive element group 12 will be hereinafter referred to as nodes 1 to 2n in this order. The switch group 15a can short any 2k-th node (k is an integer from 0 to n), that is, all the even-numbered nodes. The switch group 15b can short any (2k+1)-th node, that is, all the odd-numbered nodes.

Based on the above configuration, when the switch groups 15a and 15b are opened, the reference power supply is applied to the terminal 11a, and the terminal 11m is connected to the ground, the reference voltage is divided and multi-level (gradation) potentials are obtained at the nodes 0 to 2n+1. The selection circuit 14 functions as a D/A converter, that is, the selection circuit 14 selects one of the nodes 0 to 2n+1 and outputs a voltage applied to the selected wiring to the output terminal 16.

The terminals 11b to 11m−1 may be open. Each of the terminals 11b to 11m−1 may be externally supplied with a potential that appears in a case where the resistance of each resistor of the resistive element group 12 is ideal. In this case, errors in the D/A converter can be reduced.

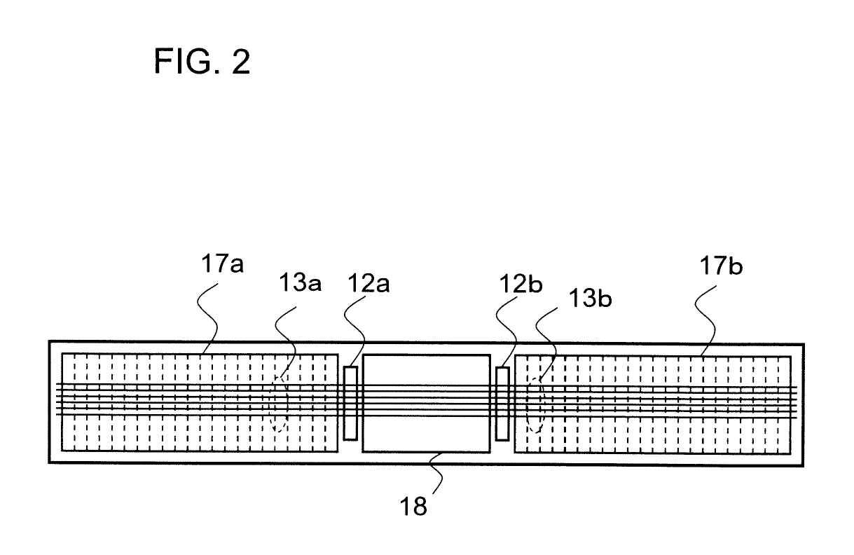

Next, a layout example of the semiconductor integrated circuit device will be described. FIG. 2 illustrates a layout of the semiconductor integrated circuit device according to the example of the present invention. In FIG. 2, the semiconductor integrated circuit device includes resistive element groups 12a and 12b, wiring groups 13a and 13b, output cell arrangement regions 17a and 17b, and a control circuit 18.

The control circuit 18 includes the switch groups 15a and 15b and the terminals 11a to 11m illustrated in FIG. 1. The control circuit 18 has a function of supplying a voltage to the terminals 11a to 11m. The resistive element groups 12a and 12b are similar to the resistive element group 12. The wiring groups 13a and 13b are similar to the wiring group 13 and extend from the control circuit 18 through the output cell arrangement regions 17a and 17b on both the sides of the control circuit 18. In the output cell arrangement regions 17a and 17b, a plurality of selection circuits 14 are arranged under arrangement regions of the wiring groups 13a and 13b.

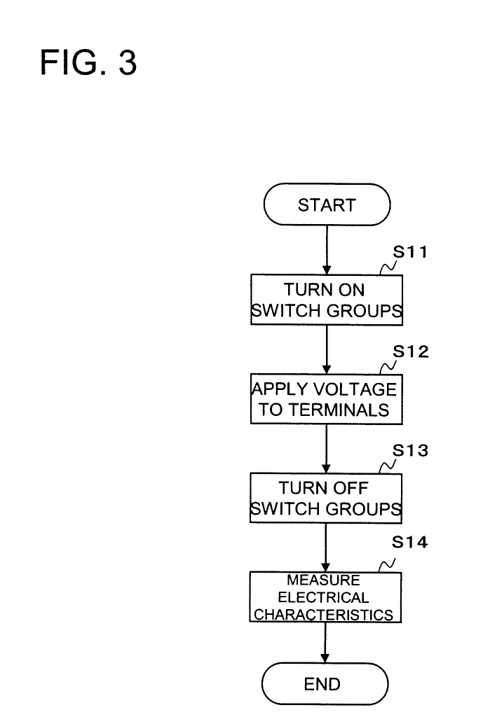

FIG. 3 is a flow chart illustrating a first test method of the semiconductor integrated circuit device according to the example of the present invention.

In step S11, the switch groups 15a and 15b are all shorted (turned on).

In step S12, a voltage (10V, for example) is applied to the terminal 11a, and the terminal 11m is connected to the ground. The voltage is applied for a prescribed period of time, for one second, for example. Appropriate values necessary to eliminate initial failures need to be set for the voltage value and voltage application time.

In step S13, the switch groups 15a and 15b are all opened (turned off).

In step S14, electrical characteristics of the resistive element group 12 are measured, and if the electrical characteristics do not fall within a predetermined range, the tested semiconductor integrated circuit device is determined as defective. The above measurement of electrical characteristics refers to general product tests, other than an aging test. More specifically, examples of the above measurement include a gradation test, a leakage current test, and a function test based on resistance precision measurement.

As described above, according to the first test method illustrated by the flow chart of FIG. 3, unreliable products can be determined by fewer test processes, and screening can be executed accurately.

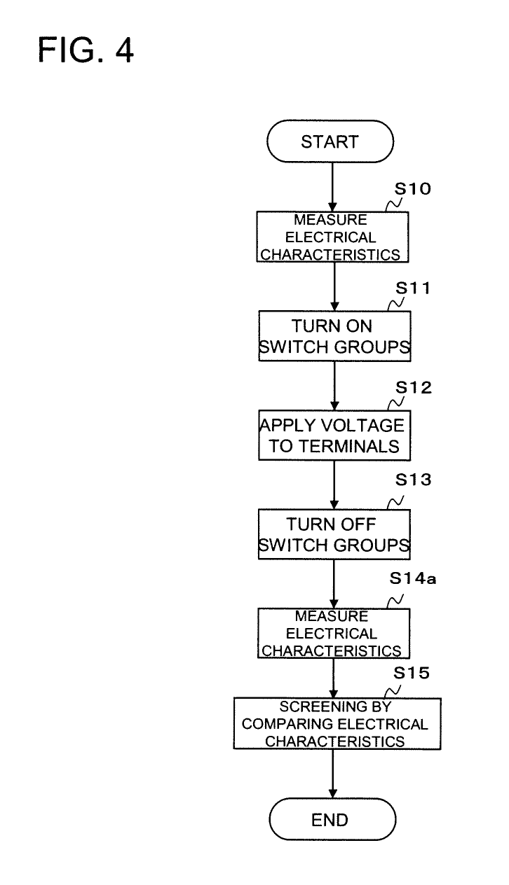

FIG. 4 is a flow chart illustrating a second test method of the semiconductor integrated circuit device according to an example of the present invention. In FIGS. 3 and 4, like reference characters denote the steps for like processes, and thus the descriptions thereof will be omitted.

In step S10, initial electrical characteristics of the resistive element group 12 are measured and the measurement results are stored. The initial electrical characteristics refer to those obtained before a voltage application to terminals in step S12 carried out later.

In step S14a, electrical characteristics of the resistive element group 12 are measured again and the measurement results are stored.

In step S15, the electrical characteristics measured in steps S10 and S14a are compared with each other. When the comparison results are greater than or equal to a predetermined value, the tested semiconductor integrated circuit device is determined as a defect.

Based on the above method for testing the semiconductor integrated circuit device, since the switch groups 15a and 15b used to short wirings are turned on and a maximum voltage is applied between neighboring wirings, unreliable products (i.e., products having certain defect) are destroyed. Subsequently, the switch groups 15a and 15b are all tuned off, and defective products are removed (discarded). Thus, by applying a maximum voltage between neighboring wirings, those products having certain problem in the reliability that might be determined as “non-defective” can be destroyed and removed.

There is a case where products are deteriorated by the voltage application carried out in step S12 and are then determined as defective, whereas there is also another case where the products are determined as defective because of original defective factor(s) thereof. According to the first test method illustrated by the flow chart of FIG. 3, these two cases cannot be distinguished.

However, according to the second test method illustrated by the flow chart of FIG. 4, the above case where products are deteriorated by the voltage application carried out in step S12 and are then determined as defective can be distinguished from the case where the products are determined as defective because of the original defective factor(s) thereof. Based on the determination results, a manufacturing process causing defective products can be identified, and feedback can be supplied to the manufacturing process. Thus, the method has an advantageous effect of improving a manufacturing yield.

The disclosure of the above Patent Document and the like is incorporated herein by reference thereto. Modifications and adjustments of the exemplary embodiments and examples are possible within the scope of the overall disclosure (including the claims) of the present invention and based on the basic technical concept of the present invention. Various combinations and selections of various disclosed elements are possible within the scope of the claims of the present invention. That is, the present invention, of course, includes various variations and modifications that could be made by those skilled in the art according to the entire disclosure including the claims and the technical concept.

What is claimed is:

1. A semiconductor integrated circuit device, comprising:
first and second terminals;
first to (2n+1)-th resistive elements (n is an integer of at least 1) connected in series between the first and second terminals;
a selection circuit selecting, assuming that a first terminal connected to one end of the first resistive element is a 0th node, a second terminal connected to the other end of the (2n+1)-th resistive element is a (2n+1)-th node, and a connection point of the other end of an i-th resistive element (i is an integer from 1 to 2n) and one end of an (i+1)-th resistive element is an i-th node, any one of the 0th to (2n+1)-th nodes and outputting a voltage applied to the selected node;
a first switch group capable of shorting any 2k-th node (k is an integer from 0 to n); and
a second switch group capable of shorting any (2k+1)-th node.

2. The semiconductor integrated circuit device according to claim 1, wherein the first and second switch groups are open in a normal operation mode and are temporarily shorted in a test mode.

3. The semiconductor integrated circuit device according to claim 1, further comprising a plurality of the selection circuits, wherein wirings, each extending from a corresponding one of the 0th to (2n+1)-th nodes, extend in parallel to each other to branch points of the plurality of selection circuits.

4. The semiconductor integrated circuit device according to claim 3, wherein the plurality of the selection circuits are arranged under a plurality of wiring arrangement regions in output cell arrangement regions.

5. A method for testing a semiconductor integrated circuit device comprising:
first and second terminals and first to (2n+1)-th resistive elements (n is an integer of at least 1) connected in series between the first and second terminals and capable of selecting, assuming that a first terminal connected to one end of a first resistive element is a 0th node, a second terminal connected to the other end of the (2n+1)-th resistive element is a (2n+1)-th node, and a connection point of the other end of an i-th resistive element (i is an integer from 1 to 2n) and one end of an (i+1)-th resistive element is an i-th node, any one of the 0th to (2n+1)-th nodes and outputting a voltage applied to the selected node, the method comprising:
(a) shorting any 2k-th node (k is an integer from 0 to n), that is, all the even-numbered nodes and any (2k+1)-th node, that is, all the odd-numbered nodes, termed “step (a)”;
(b) temporarily applying a predetermined voltage between the first and second terminals, termed “step (b)”; and
(c) opening any 2k-th node, that is, all the even-numbered nodes and any (2k+1)-th node, that is, all the odd-numbered nodes, termed “step (c)”.

6. The method for testing the semiconductor integrated circuit device according to claim 5, further comprising (d) measuring electrical characteristics of the first to (2n+1)-th resistive elements after step (c), termed “step (d)”.

7. The method for testing the semiconductor integrated circuit device according to claim 6, further comprising:
(a0) measuring initial electrical characteristics of the first to (2n+1)-th resistive elements before step (a), termed “step (a0)”; and
(e) comparing measurement results of the electrical characteristics obtained in steps (a0) and (d) after step (d), termed “step (e)”.
